(19) United States
(12) Patent Application Publication
(10) Pub. No.: US 2010/0112743 A1
(43) Pub. Date: May 6, 2010

(54) METHOD OF MANUFACTURING SEMICONDUCTOR DEVICE INCLUDING VIBRATOR WHICH IS PROVIDED WITH SIDE INSULATING FILM AND INSULATING SEPARATION REGION FORMED BY THERMAL OXIDATION

(75) Inventor: Hironobu KAWAUCHI, Kyoto (JP)

Correspondence Address: CANTOR COLBURN, LLP, 20 Church Street, 22nd Floor, Hartford, CT, 06103, US

(73) Assignee: ROHM CO., LTD., Kyoto-fu (JP)

(21) Appl. No.: 12/612,008

(22) Filed: Nov. 4, 2009

(30) Foreign Application Priority Data
Nov. 5, 2008 (JP) 2008-284626
Dec. 17, 2008 (JP) 2008-321014

(51) Int. Cl. H01L 21/302

(52) U.S. Cl. 438/52; 257/E21.214

(57) ABSTRACT

A method of manufacturing a semiconductor device includes partially etching the upper surface of the semiconductor substrate to form side grooves and expose side surfaces of the vibrators, partially etching the upper surface of the semiconductor substrate to form separation grooves where insulating separation regions between the vibrators and the semiconductor substrate are to be formed, thermally oxidizing surfaces of the separation grooves to form the insulating separation region composed of oxidized films filled in the separation grooves, thermally oxidizing the side surfaces of the vibrators to form side insulating film, and performing release etching of the semiconductor substrate using the side insulating film as a mask to expose bottom surfaces of the vibrators and form the vibrators arranged in the recess formed in the semiconductor substrate.

### CROSS REFERENCE TO RELATED APPLICATIONS AND INCORPORATION BY REFERENCE

This application is based upon and claims the benefit of priority from prior Japanese Patent Application P2008-284626 filed on Nov. 5, 2008 and prior Japanese Patent Application P2008-321014 filed on Dec. 17, 2008; the entire contents of which are incorporated by reference herein.

### BACKGROUND OF THE INVENTION

1. Field of the Invention

The present invention relates to a method of manufacturing a semiconductor device including beam-shaped vibrators.

2. Description of the Related Art

Semiconductor devices such as Micro-Electro-Mechanical system (MEMS) devices including beam-shaped vibrators, surface acoustic wave (SAW) devices, film bulk acoustic resonators (FBAR) made of piezoelectric material are used in accelerometers, gyrosensors, and the like. For example, capacitive accelerometers detecting acceleration by sensing a change in electrostatic capacity between two vibrators and the like have been put into practical use.

In order to form beam-shaped vibrators each having a free end, generally, an SOI substrate including insulating film layers and silicon layers stacked on a silicon substrate is used. The insulating film layers are used as sacrificial layers, and the silicon layers are used as free ends. On the other hand, some manufacturing methods which do not use the sacrificial layers are proposed. In a manufacturing method not using the sacrificial layers, a trench for isolation is formed between the free end of each vibrator and the semiconductor substrate to which the vibrator is fixed, and then the trench for isolation is filled with an insulating material to form an insulating separation region between the free end of the vibrator and the semiconductor substrate.

However, in such a proposed manufacturing method not using the sacrificial layers, side insulating films are formed on the side surfaces of each vibrator by chemical vapor deposition (CVD). Accordingly, the side insulating films decrease in thickness toward the bottom of each vibrator and have non-uniform thickness. When the side insulating films of the vibrators have non-uniform thickness, the semiconductor device has an unstable feature in sensing changes in electrostatic capacity between the vibrators.

### SUMMARY OF THE INVENTION

An aspect of the present invention is a method of manufacturing a semiconductor device which includes a plurality of beam-shaped vibrators each having a free end extended in a recess formed in an upper surface of a semiconductor substrate and a fixed end fixed to the semiconductor substrate. The method includes partially etching the upper surface of the semiconductor substrate to form side grooves and expose side surfaces of the vibrators; partially etching the upper surface of the semiconductor substrate to form separation grooves where insulating separation regions between the vibrators and the semiconductor substrate are to be formed; thermally oxidizing surfaces of the separation grooves to form the insulating separation region composed of oxidized films filled in the separation grooves; thermally oxidizing the side surfaces of the vibrators to form side insulating film; and performing release etching of the semiconductor substrate using the side insulating film as a mask to expose bottom surfaces of the vibrators and form the vibrators arranged in the recess formed in the semiconductor substrate.

### BRIEF DESCRIPTION OF THE DRAWINGS

FIG. 1 is a schematic view showing a structure of a semiconductor device manufactured by a method of manufacturing a semiconductor device according to a first embodiment of the present invention.

FIGS. 2A to 2D are cross-sectional views of the semiconductor device shown in FIG. 1.

FIGS. 3A to 12E are process views for illustrating the method of manufacturing a semiconductor device according to the first embodiment of the present invention.

FIG. 13 is a process cross-sectional view for illustrating the method of manufacturing a semiconductor device according to a modification of the first embodiment of the present invention.

FIG. 14 is a schematic view showing a vibrator of the semiconductor device according to the modification of the first embodiment of the present invention.

FIG. 15 is a schematic view showing free ends of vibrators of the semiconductor device according to the modification of the first embodiment of the present invention.

FIG. 16 is a schematic view showing a structure of a semiconductor device manufactured by a method of manufacturing a semiconductor device according to a second embodiment of the present invention.

FIGS. 17A to 17C are cross-sectional views of the semiconductor device shown in FIG. 16.

FIGS. 18A to 26B are process views for illustrating the method of manufacturing a semiconductor device according to the second embodiment of the present invention.

FIG. 27 is a perspective view for illustrating a method of forming a recess of the semiconductor device according to the second embodiment of the present invention.

FIG. 28 is a process cross-sectional view illustrating a method of manufacturing a semiconductor device according to a modification of the second embodiment of the present invention.

FIG. 29 is a schematic view showing a vibrator of the semiconductor device according to the modification of the second embodiment of the present invention.

FIG. 30 is a schematic view showing a structure example of the semiconductor device according to the modification of the second embodiment of the present invention.

FIG. 31 is a schematic view showing a structure of a semiconductor device according to another embodiment of the present invention.

### DETAILED DESCRIPTION OF THE INVENTION

The first and second embodiments of the present invention will be described with reference to the accompanying drawings. In the following description of the drawings, the same or similar reference numerals are applied to the same or similar parts and elements. It is to be noted that the drawings are schematic and have different relationship between thickness and planer dimensions, proportions of thickness of layers, and the like from the real ones. Accordingly, specific thicknesses and dimensions should be determined with reference to the following description. Moreover, it is obvious that some parts have different dimensional relationships or proportions throughout the drawings.

The following embodiments just shows devices and methods to embody the technical idea of the present invention, and the technical idea of the present invention does not specify materials, shapes, structures, and arrangements of the constituent components and the like to the following description. The technical idea of the present invention can be variously modified in the scope of claims.

### First Embodiment

A method of manufacturing a semiconductor device according to a first embodiment of the present invention is a method of manufacturing a semiconductor device 1 including beam vibrators 21 and 22 which have free ends within a recess 100 formed in the upper surface of a semiconductor substrate 10 and have fixed ends fixed to the semiconductor substrate 10. Specifically, the manufacturing method includes: partially etching the upper surface of the semiconductor substrate 10 to form side grooves and expose side surfaces of the vibrators 21 and 22 and simultaneously forming separation grooves in which insulating separation regions 30 between the semiconductor substrate 10 and individual vibrators 22 are to be formed; thermally oxidizing surfaces of the separation grooves to form the insulating separation regions 30 composed of oxidized films filled in the separation grooves; thermally oxidizing the side surfaces of the vibrators 21 and 22 to form the side insulating films; and performing release etching for the semiconductor substrate 10 using the side insulating films as a mask to expose bottom surfaces of the vibrators 21 and to form the vibrators 21 and 22 arranged within the recess 100, which is formed in the semiconductor substrate 10.

The vibrators 21 and 22 are beam-shaped vibrators. The semiconductor device 1 is a capacitive accelerometer detecting acceleration based on fluctuations in electrostatic capacity which are dependent on distance between the vibrators 21 and 22. The semiconductor substrate 10 can be a semiconductor substrate whose surface is oxidized by thermal oxidation, for example such as a silicon (Si) substrate.

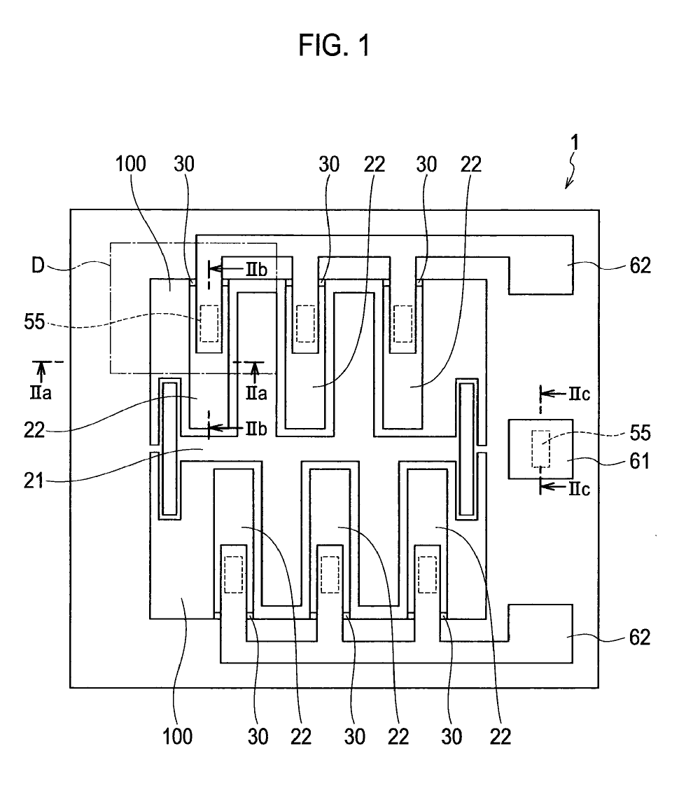

The vibrator 21 is a fishbone-shaped beam vibrator including a central stripe section and a plurality of beam sections. The central stripe section has both ends fixed to the semiconductor substrate 10 and is arranged within the recess 100. The beam sections which have fixed ends fixed to the central stripe portion and have free ends extended from the fixed ends in the recess 100. Each of the vibrators 22 is a beam vibrator which has a fixed end fixed to the edge of the semiconductor substrate 10 surrounding the recess 100 and has a free end extending within the recess 100. Between the fixed and free ends of each vibrator 22, the insulating separation region 30 is formed. As shown in FIG. 1, the vibrators 22 which are provided with the insulating separation regions 30 between the free ends thereof and the semiconductor substrate 10 and the beams of the vibrator 21 whose free ends are electrically connected to the semiconductor substrate 10 are alternately arranged, and the free ends of the vibrator 21 are interdigitated with the free ends of the vibrators 22 within the recess 100.

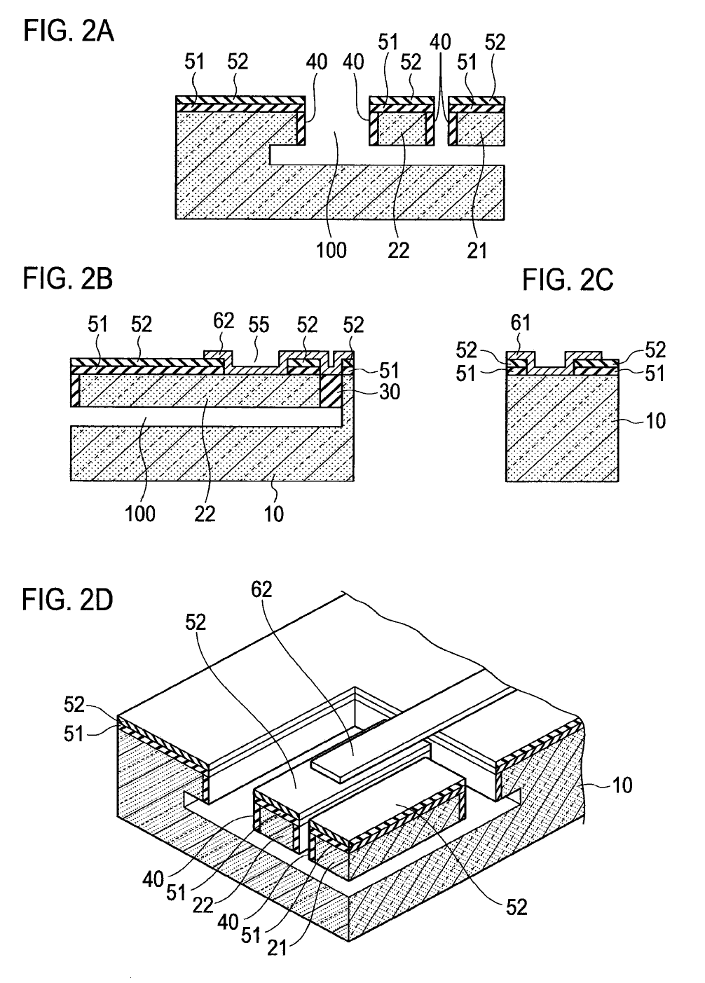

FIGS. 2A to 2C show cross-sectional views along directions IIa-IIa, IIb-IIb, and IIc-IIc of FIG. 1, respectively. FIG. 2D shows a perspective view of a region D of FIG. 1.

As shown in FIG. 2A, the side insulating films 40 are formed on the side surfaces of the vibrators 21 and 22. On the upper surfaces of the vibrators 21 and 22, upper oxidized films 51 are formed, and on the upper oxidized films 51, PSG films 52 are formed. The bottom surfaces of the vibrators 21 and 22 are exposed in the recess 100.

As shown in FIG. 2B, the upper oxidized film 51 and PSG film 52 on each vibrator 22 are partially removed to form an opening 55. A metallic electrode 62, which is electrically connected to the vibrator 22 in the opening 55, is formed on the PSG film 52. In FIG. 1, the openings 55 are indicated by dashed lines.

As shown in FIG. 2C, the upper oxidized film 51 and PSG film 52 on the semiconductor substrate 10 are partially removed to form another opening 55. A metallic electrode 61, which is in contact with the semiconductor substrate 10 in the opening 55, is formed on the PSG film 52. The metallic electrode 61 is electrically connected to the vibrator 21 through the semiconductor substrate 10.

The vibrators 21 and 22 are beam vibrators having the free ends extended in the recess 100, and the free ends of the vibrators 21 and 22 change positions thereof according to external cause including external impact. Since the free ends of the vibrator 21 are interdigitated with the free ends of the vibrators 22, the changes in positions of the vibrator 21 and vibrators 22 change the electrostatic capacity between the vibrator 21 and vibrators 22.

A description is given of an example of the operation of the semiconductor device 1 below. When an external force is applied to the semiconductor device 1, the distances between the vibrator 21 and vibrators 22 vary because of the influence of the external force. When an external force is applied to the semiconductor device 1 with voltage being applied to between the vibrators 21 and 22, the changes in distance between the vibrator 21 and vibrators 22 are sensed as a change in electrostatic capacity. The semiconductor device 1 transmits the sensed change in electrostatic capacity as a detection signal to a signal processing circuit (not shown). The signal processing circuit processes the detection signal to detect an acceleration produced in the semiconductor device 1. In other words, the semiconductor device 1 is a part of an accelerometer detecting an acceleration based on changes in electrostatic capacity between the vibrators 21 and 22. The signal processing circuit may be arranged in a same chip as the semiconductor device 1 or may be arranged in a chip different from the chip where the semiconductor device 1 is arranged.

The insulating separation regions 30, which electrically separate the vibrators 22 and the semiconductor substrate 10, are individually provided between the vibrators 22 and the semiconductor substrate 10. The vibrator 21 and each vibrator 22 therefore serve as capacitor plates. Electrical signals from the vibrators 22 are outputted through the metallic electrodes 62 to the outside of the semiconductor device 1. Electrical signals from the vibrator 21 are outputted through the metallic electrode 61, which is in contact with the semiconductor substrate 10, to the outside of the semiconductor device 1.

In the semiconductor device 1 shown in FIG. 1, in order to obtain good sensitivity, connections between the vibrator 21 and semiconductor substrate 10 are composed of springs which allow the vibrator 21 to easily vibrate. The semiconductor device 1 is therefore configured so that the electrical signals from the vibrator 21 are transmitted to the metallic electrode 61 through the semiconductor substrate 10. However, the vibrator 21 and metallic electrode 61 may be directly connected with the insulating separation regions 30 being provided between the semiconductor substrate 10 and the vibrator 21.

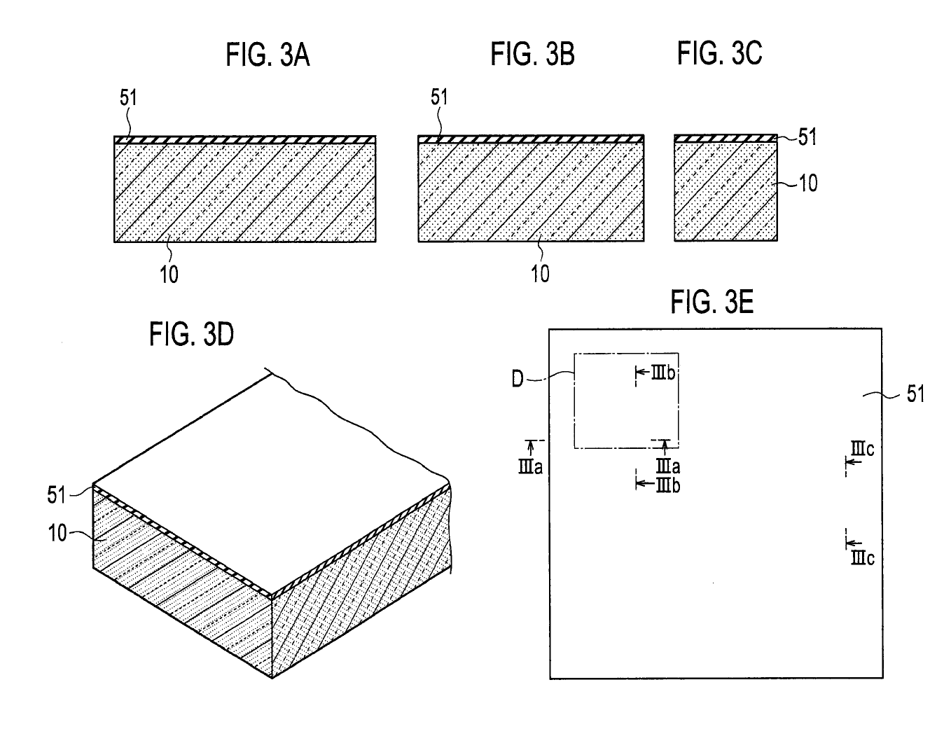

With reference to FIGS. 3A to 12E, a description is given of a method of manufacturing a semiconductor device according to the first embodiment of the present invention. FIGS. 3A, 4A, 5A, 6A, 7A, 8A, 9A, 10A, 11A, and 12A are cross-sectional views taken in a same direction as that of FIG. 2A; FIGS. 3B, 4B, 5B, 6B, 7B, 8B, 9B, 10B, 11B, and 12B are cross-sectional views taken in a same direction as that of FIG. 2B; and FIGS. 3C, 4C, 5C, 6C, 7C, 8C, 9C, 10C, 11C, and 12C are cross-sectional views taken in a same direction as that of FIG. 2C. FIG. 2D is a perspective view of a region same as the region D, and FIGS. 3E to 12E are top views of the same. The direction of the cross sections of FIGS. 3A to 12C and the positions of the region D of FIGS. 3D, 4D, 5D, 6D, 7D, 8D, 9D, 10D, 11D, and 12D are shown in FIGS. 3E, 4E, 5E, 6E, 7E, 8E, 9E, 10E, 11E, and 12E. The later-described method of manufacturing a semiconductor device is an example, and it is obvious that the present invention can be implemented by other various manufacturing methods including modifications thereof.

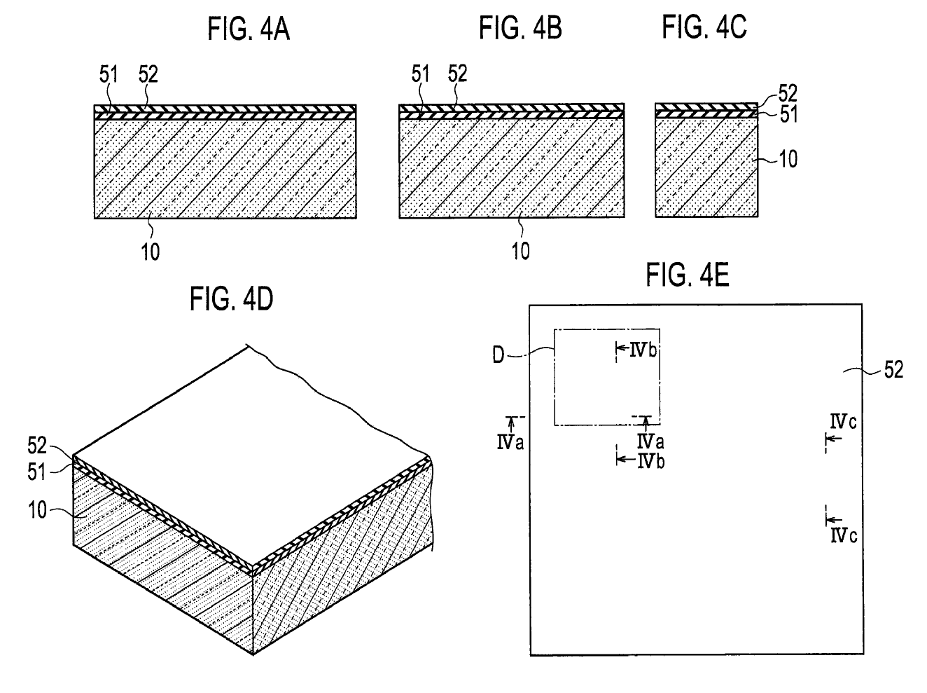

(a) As shown in FIGS. 3A to 3E, the upper surface of the semiconductor substrate 10, which is a silicon substrate, is thermally oxidized to form the upper oxidized film 51. The upper oxidized film 51 has a thickness of about 500 nm, for example. As shown in FIGS. 4A to 4E, on the upper oxidized film 51, the PSG film 52 with a thickness of about 1 μm is formed by CVD or the like, thus forming an upper insulating film including the upper oxidized film 51 and PSG film 52.

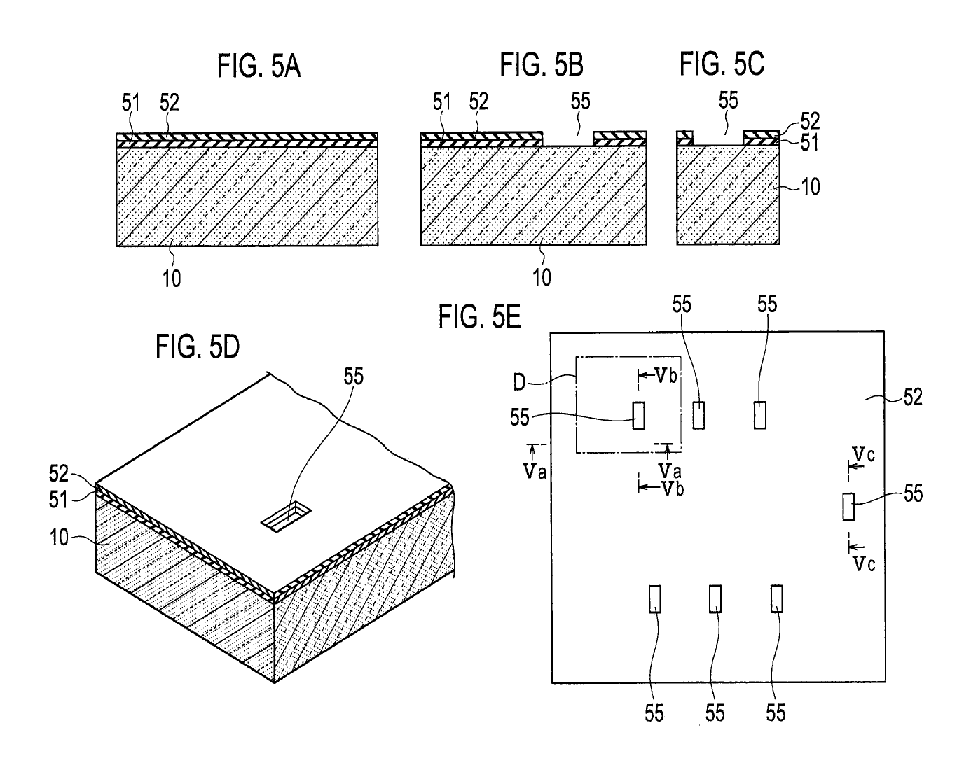

(b) The upper insulating film is partially removed by selective etching trough a photoresist mask using a photolithography technique to form the openings 55 as shown in FIGS. 5A to 5E.

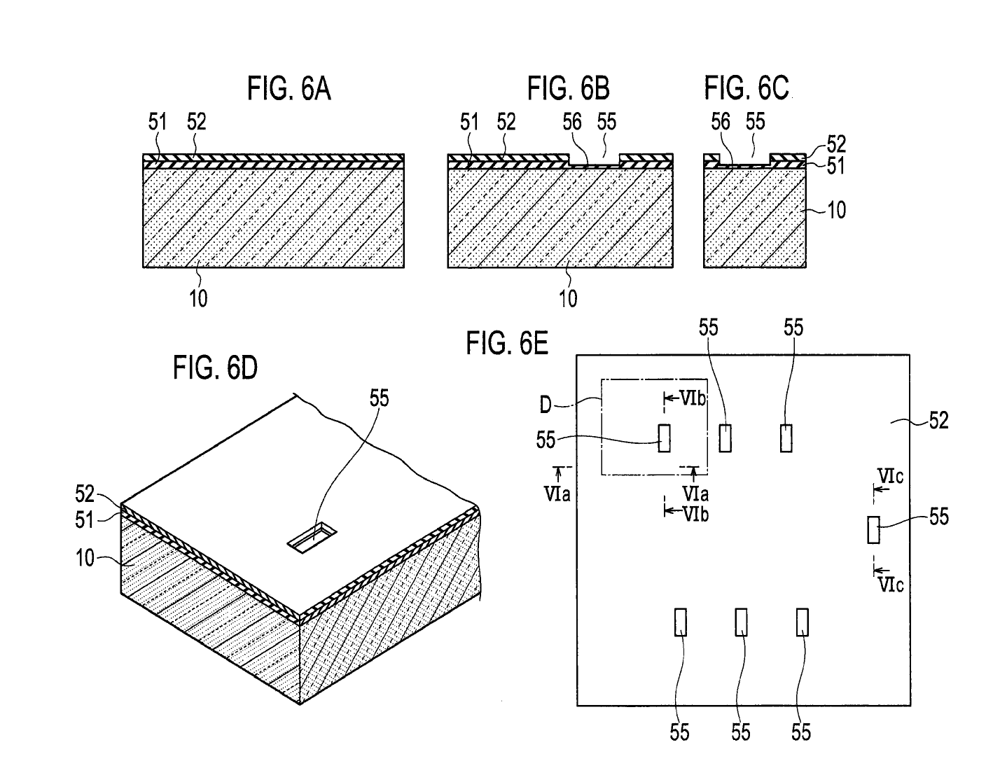

(c) In order to prevent crystal defects due to a nitride silicon (SiN) film 54 later described, the upper surface of the semiconductor substrate 10 exposed in each opening 55 is thermally oxidized to about 50 nm to form a sacrificial oxidized film 56 as shown in FIGS. 6A to 6E.

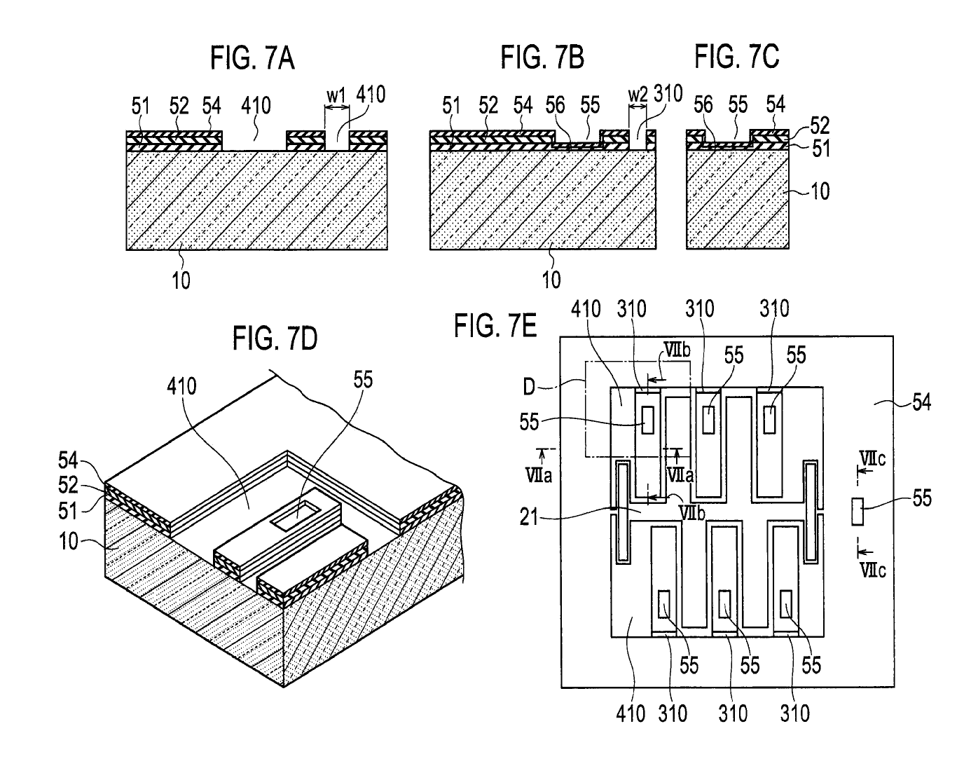

(d) All over the semiconductor substrate 10, the SiN film 54 with a thickness of about 150 to 350 nm is formed by low pressure CVD or the like. Subsequently, using a photolithography technique or the like, the SiN, PSG, and upper oxidized films 54, 52, and 51 are patterned to partially expose the upper surface of the semiconductor substrate 10. In other words, as shown in FIGS. 7A to 7E, openings 410, in which the upper surface of the semiconductor substrate 10 in a region where the recess 100 is to be formed is exposed, are formed. Moreover, openings 310, in which the upper surface of the semiconductor substrate 10 in regions where the insulating separation regions 30 are to be formed are exposed, are formed. Width W1 of the openings 410, which is a distance between each beam section of the vibrator 21 and the vibrator 22 adjacent thereto, is 2 μm, for example. Width W2 of each opening 310 in a direction perpendicular to the direction that the insulating separation region 30 extends is 0.5 μm, for example.

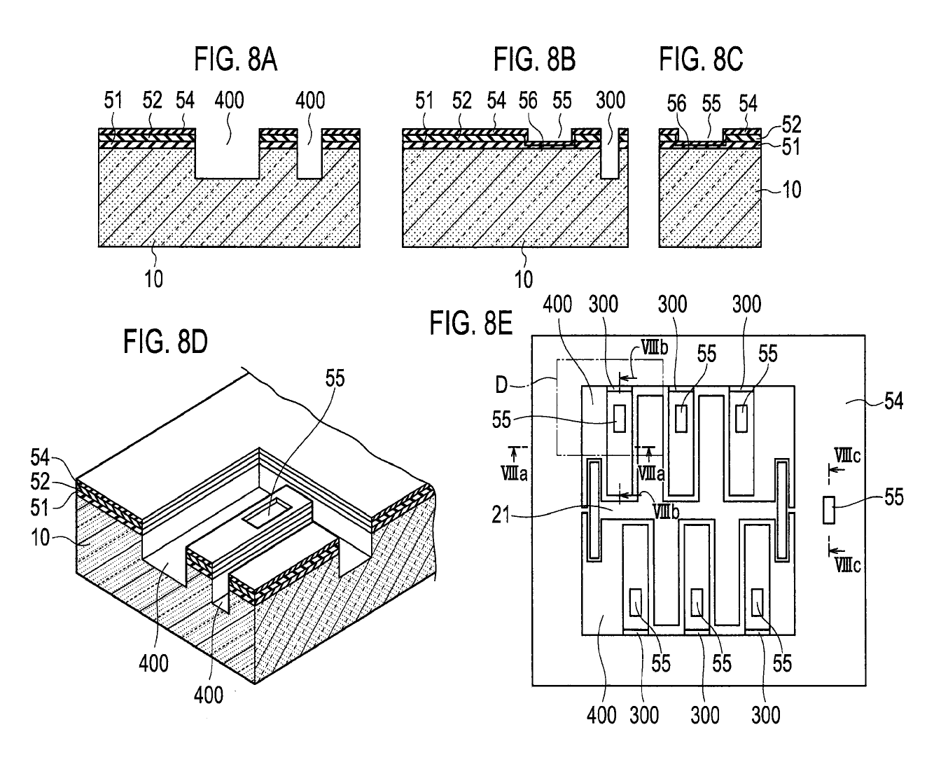

(e) As shown in FIGS. 8A to 8E, upper part of the semiconductor substrate 10 is partially etched using the patterned SiN film 54 as a mask. Specifically, upper portions of the semiconductor substrate 10 exposed in the openings 410 are etched to form the side grooves 400 and expose the side surfaces of the vibrators 21 and 22. Simultaneously with the formation of the side grooves 400, upper portions of the semiconductor substrate 10 which are exposed in the openings 310 are etched to form the separation grooves 300. Depths of the side grooves 410 and separation grooves 300 are about 25 μm, for example. The etching to form the side surface grooves 410 and separation grooves 300 can be Bosch process using deep reactive ion etching (D-RIE) or the like.

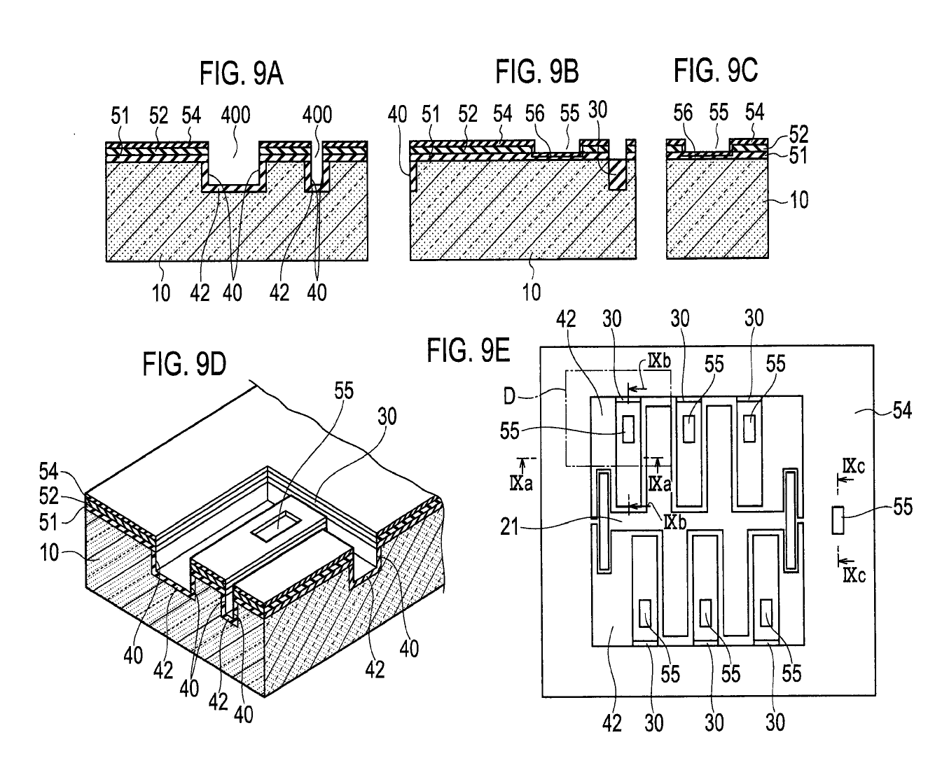

(f) As shown in FIGS. 9A to 9E, the surface of each side groove 400 is thermally oxidized to form the side insulating films 40 on the side surfaces of the side groove 400 and form a bottom insulating film 42 on the bottom surface of the side surface groove 400. The side and bottom insulating films 40 and 42 have thicknesses of about 1 to 2 μm, for example. The surface of each separation groove 300 is thermally oxidized simultaneously with the thermal oxidization of the surfaces of the side grooves 400 to fill the separation grooves 300 with thermal oxidized films, thus forming the insulting separation regions 30. After the separation grooves 300 are filled with the oxidized films, the thermal oxidization process at the surfaces of the separation grooves 300 stops.

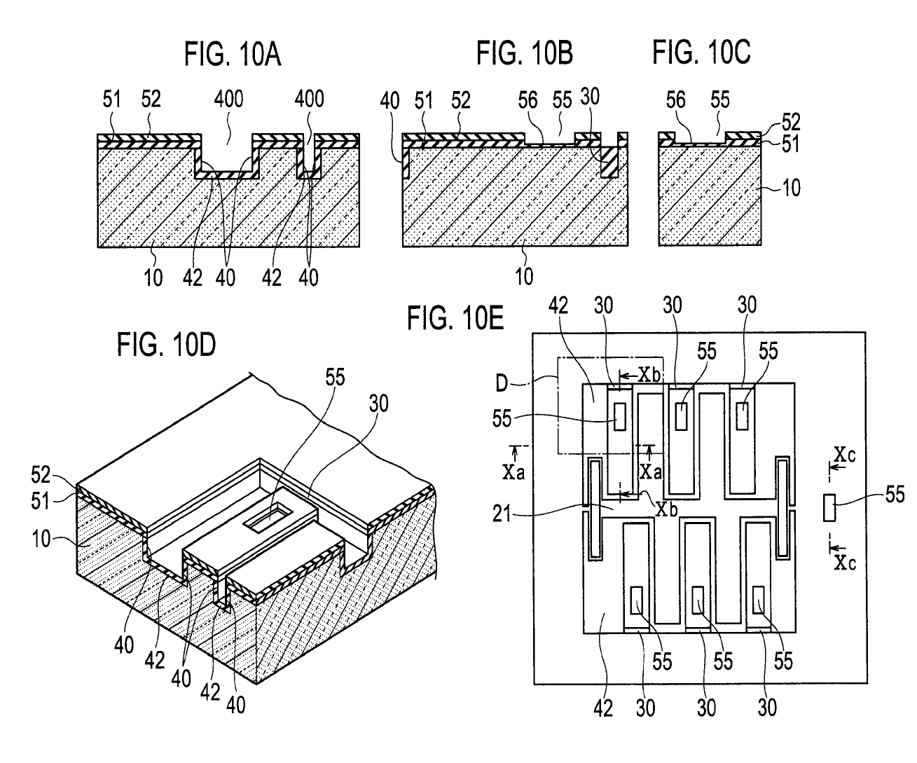

(g) As shown in FIGS. 10A to 10E, the SiN film 54 is removed. Subsequently, the sacrificial oxidized films 56 exposed in the bottom surfaces of the openings 55 are removed using buffered hydrofluoric acid or hydrofluoric acid.

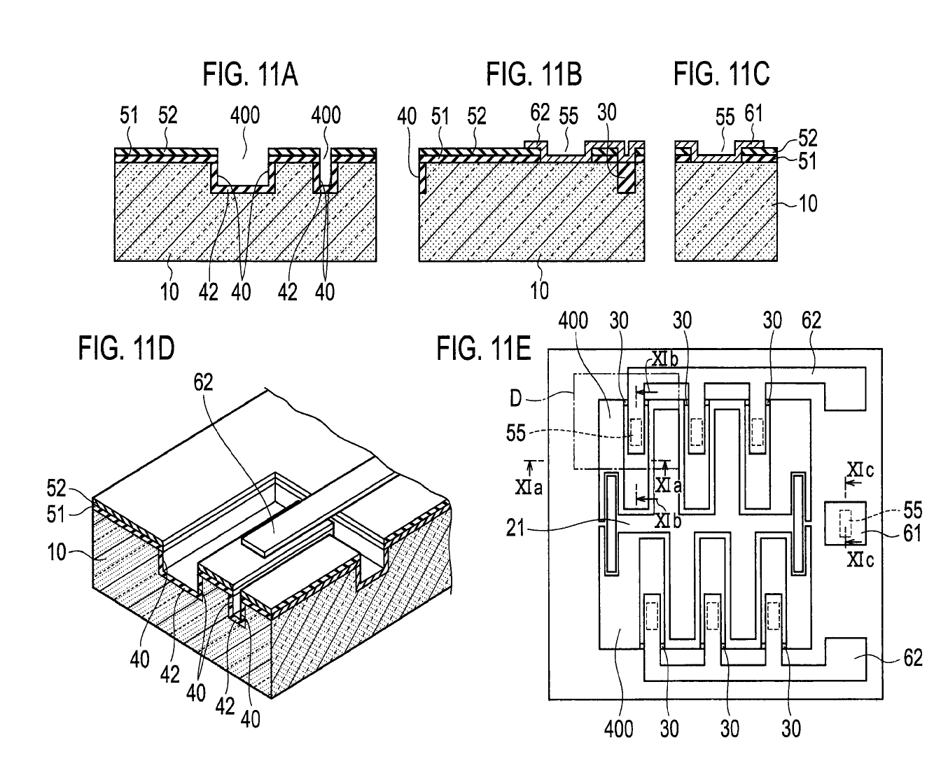

(h) As shown in FIGS. 11A to 11E, the metallic electrodes 61 and 62 are formed into predetermined patterns using a lift-off process or the like. The metallic electrodes 61 and 62 can be made of aluminum (Al) films, copper (Cu) films, or the like. For example, a photoresist film for the lift-off is formed over the upper surface of the semiconductor substrate 10 and is then patterned using a photolithography technique or the like. Subsequently, an Al film with a thickness of about 1 to 3 μm is formed over the upper surface of the semiconductor substrate 10 by sputtering or vapor deposition. The Al film is then partially removed by liftoff using the photoresist film, thus forming the metallic electrodes 61 and 62 of the Al film into the predetermined patterns. Specifically, the metallic electrode 61, which is electrically connected to the vibrator 21 through the semiconductor substrate 10 at the opening 55, and the metallic electrodes 62, which are electrically connected to the respective vibrators 22 at the openings 55, are formed on the PSG films 52. Changes in electrostatic capacity sensed between the vibrator 21 and vibrators 22 are outputted to the outside of the semiconductor device 1 through the metallic electrodes 61 and 62.

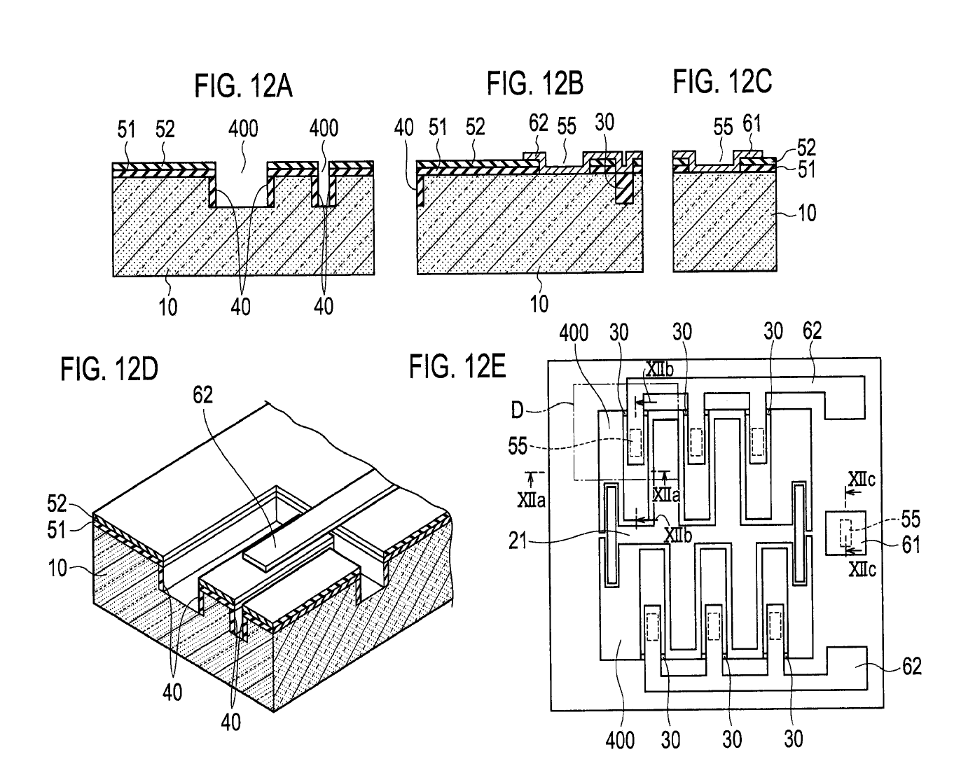

(i) As shown in FIGS. 12A to 12E, the bottom insulating films 42 exposed in the bottom surfaces of the side grooves 400 are removed by an RIE process. Because this RIE process is an anisotropic etching process, the side insulating films 40 are not etched and remain on the side surfaces of the side grooves 400.

(j) Exposed upper portions of the upper surface of the semiconductor substrate 10 are removed by etching using the PSG films 52 and side insulating films 40 as a mask to expose bottom surfaces of the vibrators 21 and 22. At the etching of the semiconductor substrate 10, an isotropic etcher using xenon difluoride (XeF₂) or the like can be used. By release etching separating the semiconductor substrate 10 and the bottom surfaces of the vibrators 21 and 22, the recess 100 is formed in the upper surface of the semiconductor substrate 10. The vibrators 21 and 22 are thus arranged in the recess 100. In such a manner, the semiconductor device 1 according to the first embodiment of the present invention is completed.

In the above description, as shown in FIGS. 5A to 5E, the openings 55 are formed immediately after the step of forming the PSG films 52. However, for example, the openings 55 may be formed after the step of forming the side insulating films 40 and insulating separation regions 30 shown in FIGS. 9A to 9E.

The side surface grooves 400 and separation grooves 300 are not necessarily formed simultaneously. However, by simultaneously forming the side grooves 400 and separation grooves 300, the side grooves 400 and separation grooves 300 can be positioned with higher accuracy. Moreover, the manufacturing process can be shortened.

As described above, the side insulating films 40 provided on the side surfaces of the vibrators 21 and 22 and the insulating separation regions 30 composed of the oxidized films filled in the separation grooves 300 are formed by thermal oxidation. Accordingly, the width w2 of the separation grooves 300 is preferably not more than 1 μm. When the width w2 is 1 μm, for example, the thickness of the side insulating films 40, which are formed on the side surfaces of the semiconductor substrate 10 by thermal oxidation, is set to about 2 μm. When the width w2 is 0.5 μm, the thickness of the side insulating films 40 may be about 1.5 μm. In the case of simultaneously forming the insulating separation regions 30 and side insulating films 40, the side insulating films 40 are preferably formed to a thickness about 1.5 times the width w2 in order to flatten the upper surfaces of the insulating separation regions 30. Long time thermal oxidation roughens the upper surfaces of the insulating separation regions 30.

By making the width w2 minute as described above, the separation grooves 300 can be filled with the oxidized films by only the step of thermal oxidation. Moreover, by simultaneously forming the side grooves 400 and separation grooves 300 at the thermal oxidation step, the side insulating films 40 and insulating separation regions 30 can be positioned with higher accuracy, and the number of manufacturing steps can be reduced.

In the semiconductor device 1, since the side surfaces of the vibrators 21 and 22 are covered with the side insulating films 40, the semiconductor substrate 10 is horizontally etched at the position deeper than the side insulating films 40 to expose the bottom surfaces of the vibrators 21 and 22. Accordingly, the thicknesses of the vibrator 21 and vibrators 22 are determined by the depth of the side grooves 400. In other words, the thicknesses of the vibrator 21 and vibrators 22 depend on the performance of the D-RIE apparatus. By using a D-RIE apparatus with an aspect ratio of 60 to 100, for example, the thicknesses of the vibrators 21 and 22 can be set to 60 to 100 μm when the width w2 is 1 μm. On the other hand, if the side insulating films 40 are formed by CVD, the depth to which the side insulating films 40 can be stably formed is 20 to 25 μm.

The bottom surfaces of the vibrators 21 and 22 are a little etched when the recess 100 is formed because the bottom surfaces of the vibrators 21 and 22 are not covered with insulating films. However, the bottom surfaces of the insulating separation regions 30 and vibrators 21 and 22 which are exposed in the recess 100 are substantially in a same plane.

As described above, in the method of manufacturing the semiconductor device 1 according to the first embodiment of the present invention, the formation of the side grooves 400 to expose the side surfaces of the vibrators 21 and 22 is simultaneously carried out with the formation of the separation grooves 300. Accordingly, the

D-RIE apparatus is used at only one step, preventing an increase in the manufacturing process. Moreover, the side insulating films 40 on the side surfaces of the vibrators 21 and 22 and the insulating separation regions 30, which are formed by filling the separation grooves 300, are formed by thermal oxidation. Accordingly, unlike the method of forming the side insulating films 40 by CVD or the like, the side insulating films 40 can have uniform thickness and stable quality. According to the method of manufacturing a semiconductor device according to the first embodiment of the present invention, it is possible to provide a method of manufacturing a semiconductor device which can prevent an increase in the manufacturing process and can provide a semiconductor device with stable electrostatic capacity between the vibrators.

### <Modification>

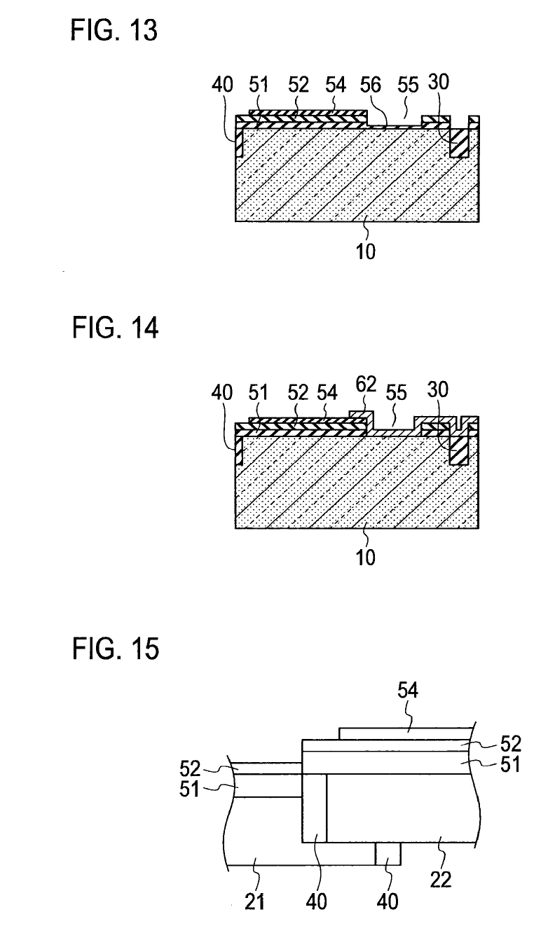

FIGS. 10A to 10E show an example in which all of the SiN films 54 on the vibrators 21 and 22 are removed. In order to detect a vertical acceleration, however, the SiN films 54 on the vibrator 21 or vibrators 22 may be partially left. Herein, the vertical acceleration is acceleration in the thickness direction of the semiconductor substrate 10. FIG. 13 shows an example in which the SiN films 54 on the vibrators 22 are not removed. FIG. 13 is a cross-sectional view of the same region as FIG. 10B.

When the SiN films 54 on any of the vibrator 21 and vibrators 22 are left, because of the difference in stress therebetween, warpage of the vibrator 21 is different from warpage of the vibrators 22. When the SiN films 54 on the vibrators 22 are left as shown in FIG. 14, the upper surfaces of the free ends of the vibrators 22 are raised higher than the upper surfaces of the free ends of the vibrator 21 as shown in FIG. 15. The vertical acceleration can be thus detected.

### Second Embodiment

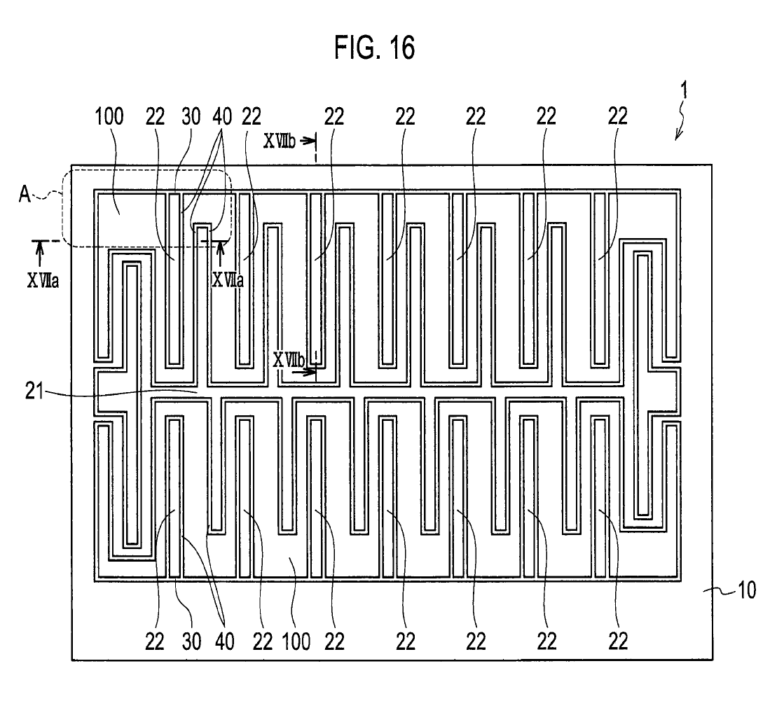

A method of manufacturing a semiconductor device according to a second embodiment is a method of manufacturing the semiconductor device 1 including beam-shaped vibrators 21 and 22 having fixed ends which are fixed to the semiconductor substrate 10 as shown in FIG. 16. Specifically, the manufacturing method includes: in the upper surface of the semiconductor substrate 10, forming side grooves in which side insulating films 40 of the vibrators 21 and 22 are to be formed and forming separation grooves in which insulating separation regions 30 between the semiconductor substrate 10 and individual vibrators 22 are to be formed; thermally oxidizing surfaces of the side grooves and separation grooves to simultaneously form the side insulating films 40 composed of oxidized films filled in the side grooves and the insulating separation regions composed of oxidized films filled in the separation grooves; and etching the semiconductor substrate 10 using the side insulating films 40 and upper insulating films on the semiconductor substrate 10 as a mask to form the vibrators 21 and 22 arranged in the recess 100 formed in the surface of the semiconductor substrate 10.

The vibrators 21 and 22 are beam-shaped vibrators. The semiconductor device 1 is a capacitive accelerometer detecting acceleration using fluctuations in electrostatic capacity which depends on distances between the vibrator 21 and the vibrators 22.

The vibrator 21 is a fishbone-shaped beam vibrator including a central stripe section and a plurality of beam sections. The central stripe section has both ends fixed to the semiconductor substrate 10. The beam sections have fixed ends fixed to the central stripe section and have free ends extended in the recess 100. Each of the vibrators 22 is a beam vibrator having a fixed end which is fixed to the semiconductor substrate 10 and having a free end extending in the recess 100. As shown in FIG. 16, the free ends of the vibrator 21 are interdigitated with the free ends of the vibrators 22.

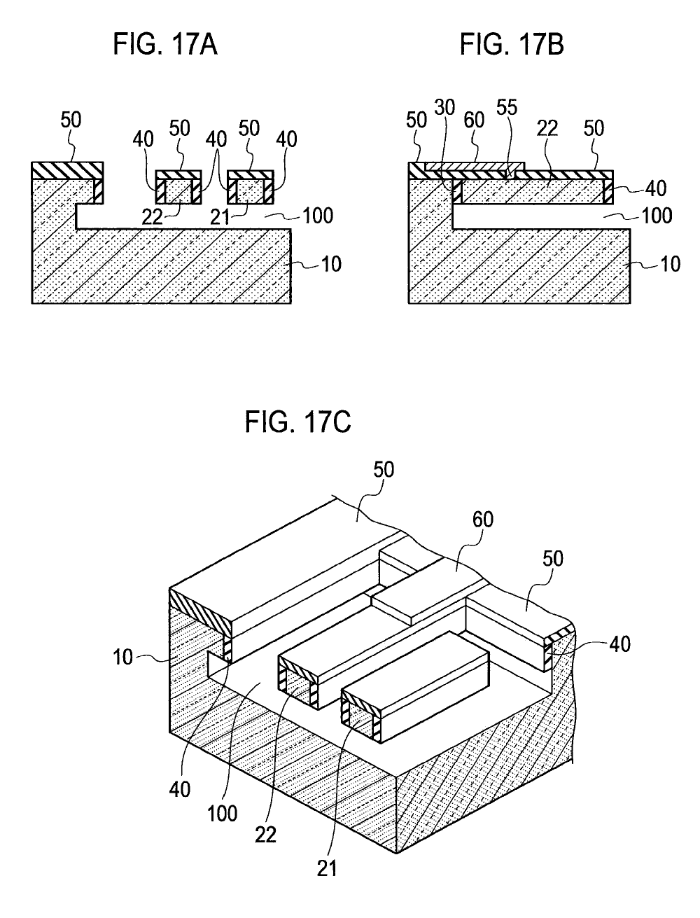

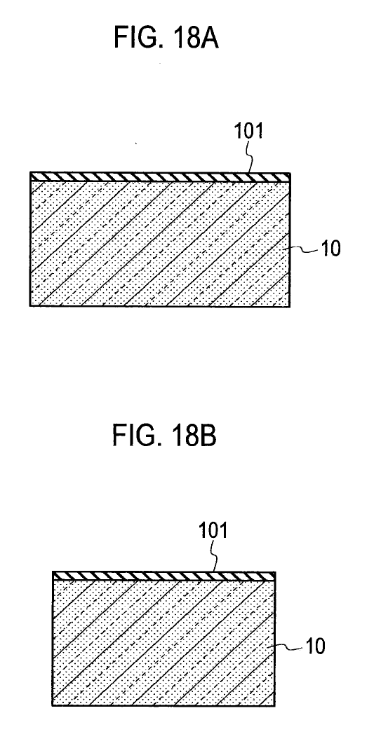

FIGS. 17A and 17B show cross-sectional views along directions of IXVIIa-XVIIa and XVIIb-XVIIb of FIG. 16, respectively. FIG. 17C shows a perspective view of a region A of FIG. 16.

As shown in FIG. 17A, side insulating films 40 are formed on the side surfaces of the vibrators 21 and 22. On the upper surfaces of the vibrators 21 and 22, upper oxidized films 50 are formed. Each of the upper insulating films 50 is composed of a single layer in FIG. 17 but may be composed of a plurality of layers. For example, as shown in the first embodiment, each upper insulating film 50 may be a film stack of an upper oxidized film 51 and a PSG film 52. The bottom surfaces of the vibrators 21 and 22 are exposed in the recess 100. Herein, the upper insulating films 50 are not shown in FIG. 16.

As shown in FIG. 17B, a part of the upper insulating film 50 on each vibrator 22 is removed to form an opening 55. A metallic electrode 60, which is electrically connected to the vibrator 22 in the opening 55, is formed on the upper insulating film 50. In FIG. 16, the openings 55 and metallic electrodes 60 are not shown.

The vibrators 21 and 22 are beam-shaped vibrators having the free ends extended in the recess 100, and the free ends of the vibrators 21 and 22 change positions thereof according to external cause including external impact. Since the free ends of the vibrator 21 are interdigitated with the free ends of the vibrators 22, changes in positions of the vibrators 21 and 22 change the electrostatic capacity between the vibrator 21 and vibrators 22. The semiconductor device 1 detects acceleration based on the change in electrostatic capacity between the vibrator 21 and vibrators 22.

The insulating separation regions 30, which electrically separate the vibrators 22 and the semiconductor substrate 10, are individually provided between the vibrators 22 and the semiconductor substrate 10. The vibrator 21 and vibrators 22 thus serve as capacitor plates. Electrical signals from the vibrators 22 are outputted to the outside of the semiconductor device 1 through the metallic electrodes 60. Electrical signals from the vibrator 21 are outputted to the outside of the semiconductor device 1 through the semiconductor substrate 10.

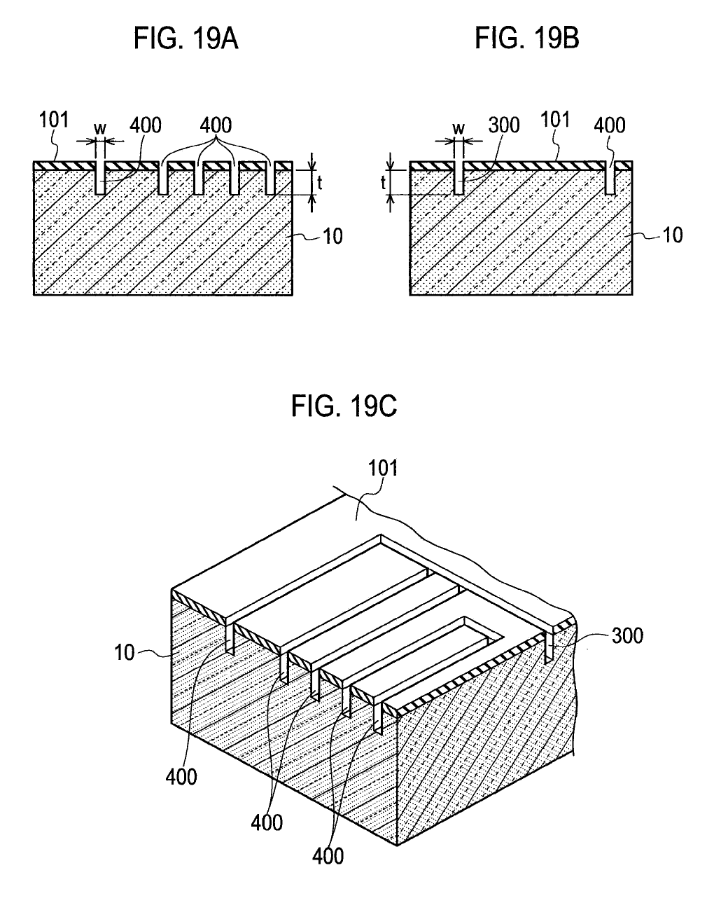

With reference to FIGS. 18A to 27, a description is given of a method of manufacturing a semiconductor device according to the second embodiment of the present invention. FIGS. 18A, 19A, 20A, 21A, 22A, 23A, 24A, 25A, and 26A are cross-sectional views taken along a same direction as that of FIG. 17A; FIGS. 18B, 19B, 20B, 21B, 22B, 23B, 24B, 25B, and 26B are cross-sectional views taken along a same direction as that of FIG. 17B; and FIGS. 19C, 20C, 21C, 22C, and 23C are perspective views of a region same as the region A of FIG. 16. The below-described method of manufacturing a semiconductor device is an example, and it is obvious that the present invention can be implemented by other various manufacturing methods including modifications thereof.

(a) As shown in FIGS. 18A and 18B, the upper surface of the semiconductor substrate 10, which is a silicon substrate, is thermally oxidized to form an oxidized silicon film 101.

(b) The oxidized silicon film 101 is partially removed by etching through a photoresist mask using a photolithography technique or the like to pattern the oxidized silicon film 101. Specifically, portions of the oxidized silicon film 101 on regions of the side grooves 400 where the side insulating films 40 are to be formed and on regions of the separation grooves 300 where the insulating separation regions 30 are to be formed are removed.

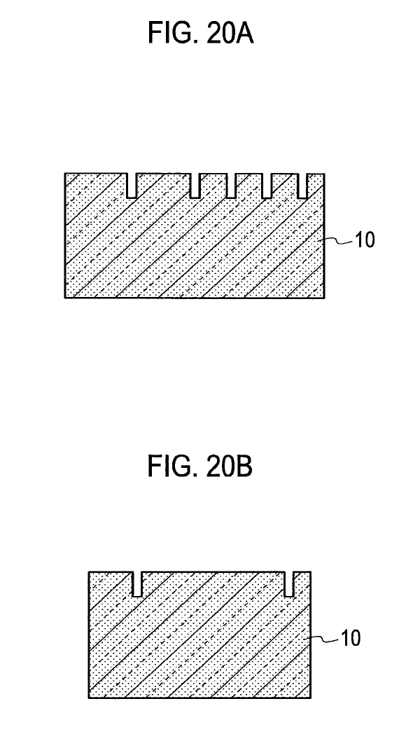

Subsequently, the upper surface of the semiconductor substrate 10 is etched using the patterned oxidized silicon film 101 as a mask to form the side grooves 400 and separation grooves 300 as shown in FIGS. 19A to 19C. Groove width W of the side grooves 400 and separation grooves 300 is about 0.5 to 1 μm, for example. Depth t of the side grooves 400 and separation grooves 300 is about 30 μm, for example. At the etching to form the side grooves 400 and separation grooves 300, D-RIE or the like can be employed. Thereafter, the oxidized silicon film 101 is removed as shown in FIGS. 20A and 20B.

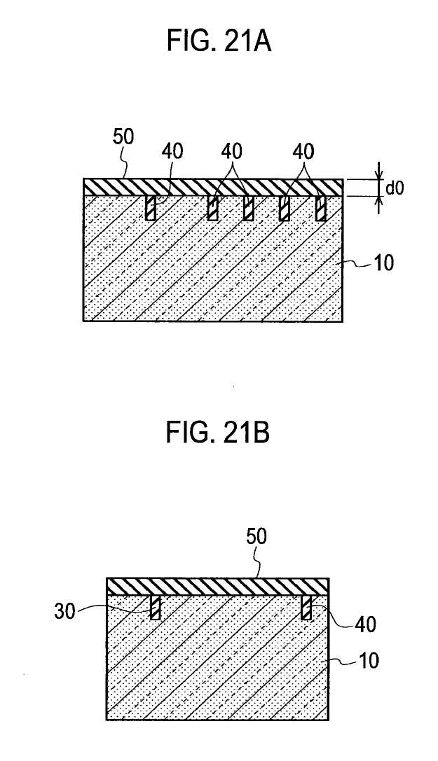

(c) The surfaces of the side grooves 400 and separation grooves 300 are thermally oxidized to simultaneously form the side insulating films 40 composed of oxidized films filled in the side grooves 400 and the insulating separation films 30 composed of oxidized films filled in the separation grooves 300. At this time, the upper surface of the semiconductor substrate 10 is thermally oxidized to form the upper insulating film 50 as shown in FIGS. 21A and 21B. The upper insulating film 50 has a thickness d0 of about 2 μm, for example. After the side grooves 400 and separation grooves 300 are filled with the oxidized films, the thermal oxidation process at the surfaces of the side grooves 400 and separation grooves 300 stops.

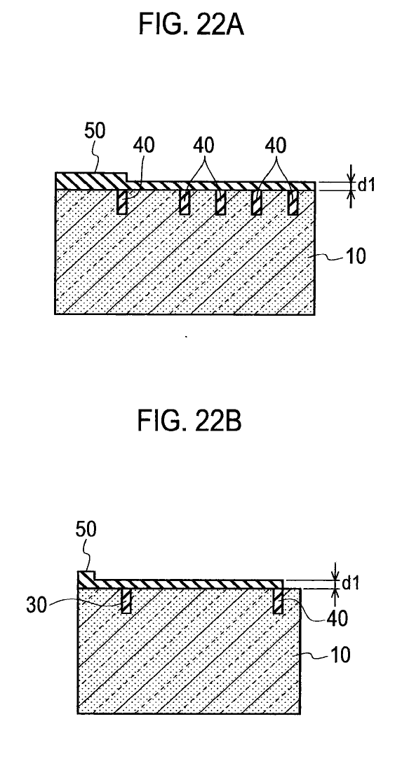

(d) As shown in FIGS. 22A and 22B, the upper insulating films 50 on the vibrators 21 and 22 are etched back to a thickness d1 of about 0.5 μm. For example, the surfaces of the upper insulating films 50 on the vibrators and 22 are etched back using a photolithography technique through a photoresist mask or the like.

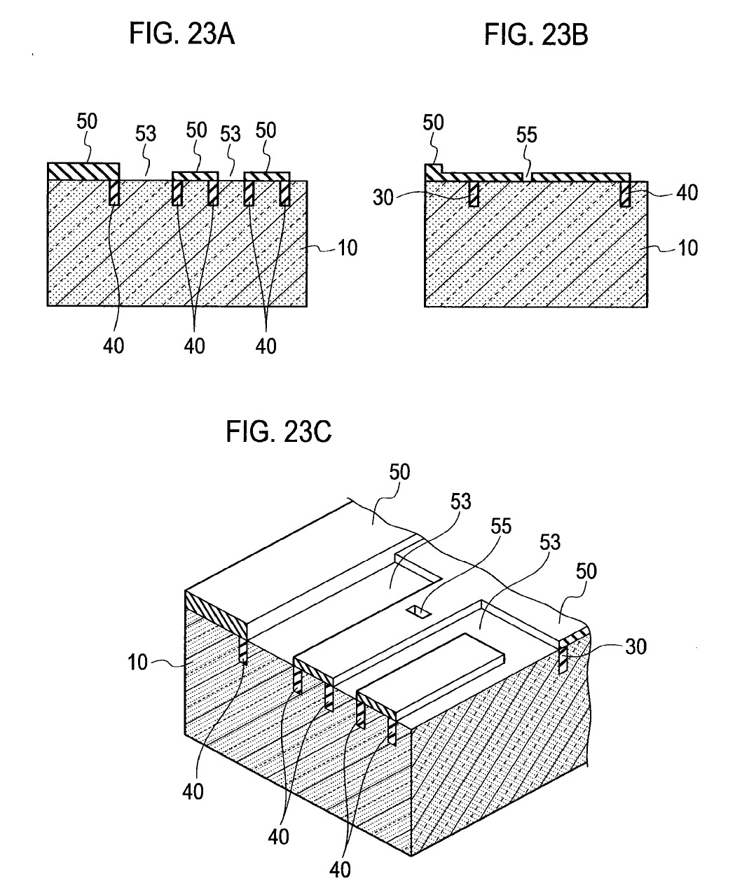

(e) As shown in FIGS. 23A to 23C, the upper insulating films 50 on regions of the semiconductor substrate 10 which are to be etched to form openings 53 for forming recesses. Simultaneously, an opening 55 for contact through which an electrical signal from each vibrator 22 is outputted is formed. The openings 53 and 55 can be formed using a photolithography technique through a photoresist mask or the like.

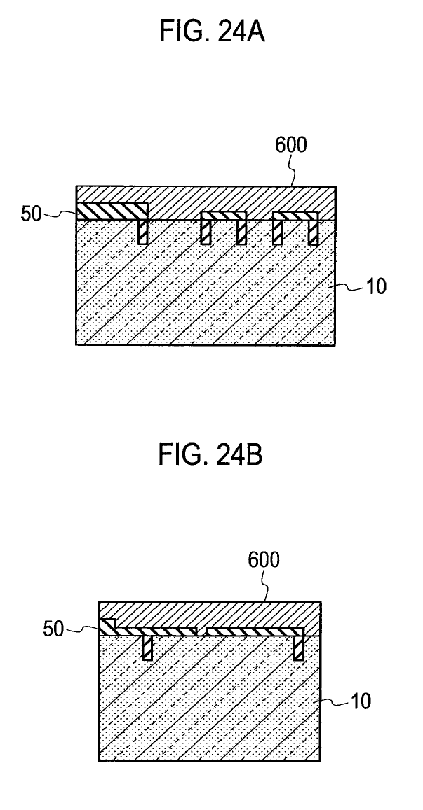

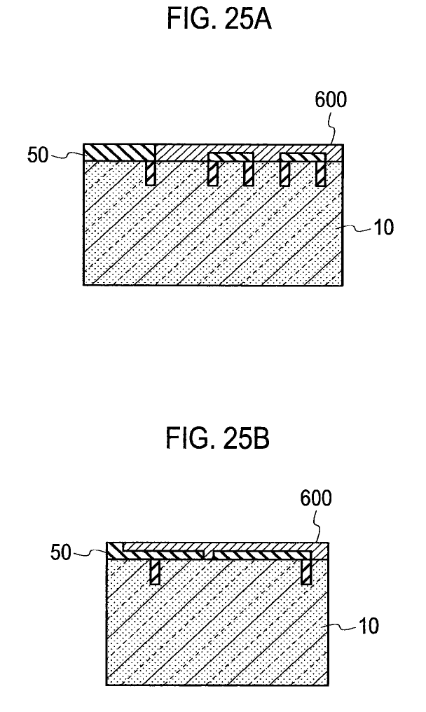

(f) As shown in FIGS. 24A and 24B, a conductor layer 600 is formed on the entire upper surface of the semiconductor substrate 10 so as to fill the openings 55. The conductor layer 600 can be composed of an aluminum (Al) or copper (Cu) film or the like. For example, an Al film with a thickness of about 1 to 3 μm is formed by sputtering. Thereafter, if necessary, the surface of the conductor layer 600 is flattened by chemical-mechanical polishing (CMP) or the like. For example, as shown in FIGS. 25A and 25B, the surface of the conductor layer 600 is etched to expose the upper insulating films 50 for flattening.

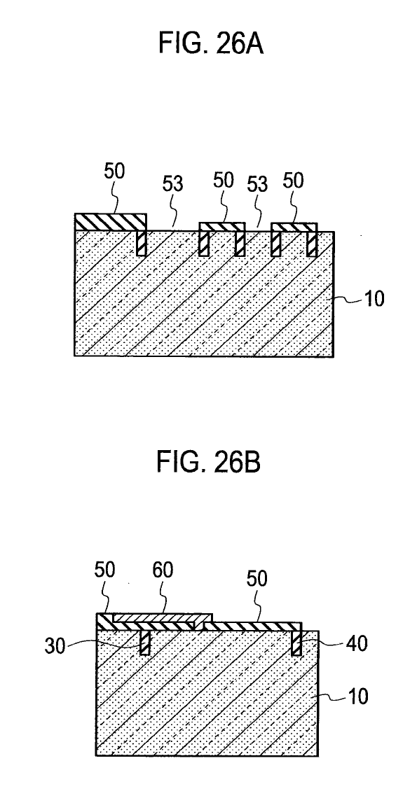

(g) The conductor layer 600 is patterned using a photolithography technique or the like to form the metallic electrodes 60. Specifically, as shown in FIGS. 26A and 26B, the metallic electrode 60 electrically connected to each vibrator 22 in the opening 55 is formed on the upper insulating film 50. Changes in electrostatic capacity sensed between the vibrator 21 and vibrators 22 are outputted through the metallic electrodes 60 to the outside of the vibrators 22. Thereafter, the rear surface of the semiconductor substrate 10 is polished so that the semiconductor substrate 10 has a desired thickness if necessary.

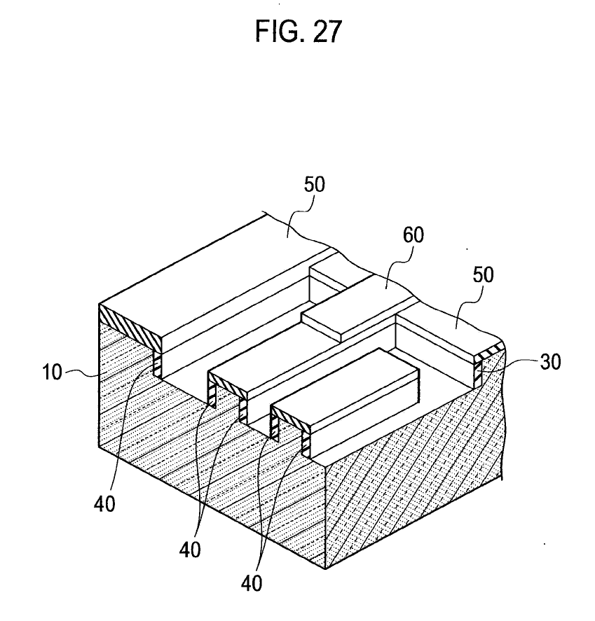

(h) The surface of the semiconductor substrate 10 is etched using the side insulating films 40 and upper insulating films 50 as a mask to form the side surface portions of the vibrators 21 and 22 as shown in FIG. 27. In the case of etching the semiconductor substrate 10 by isotropic etching, etching to form the side surfaces of the vibrators 21 and 22 is performed, and then etching to form the bottom surfaces of the vibrators 21 and 22 is continuously performed. By such release etching of the semiconductor substrate 10, the recess 100 is formed in the surface of the semiconductor substrate 10, and the vibrators 21 and 22 are arranged in the recess 100. At the release etching, an isotropic etcher using xenon difluoride (XeF₂) or the like can be used. In such a manner, the semiconductor device 1 according to the second embodiment of the present invention is completed.

As previously described, in the method of manufacturing the semiconductor device 1 according to the first embodiment, the side grooves 400 are formed in the region where the recess 100 is to be formed, or the region where spaces between the vibrators 21 and 22 are to be formed. On the other hand, in the method of manufacturing the semiconductor device 1 according to the second embodiment, the side grooves 400 are formed only in the region where the side insulating films 40 are to be formed. After the side insulating films 40 are formed, the portions of the semiconductor substrate 10 between the vibrators 21 and 22 are etched.

In the method of manufacturing the semiconductor device 1 according to the second embodiment, the side insulating films 40 composed of the oxidized films filled in the side grooves 400 and the insulating separation regions 30 composed of the oxide films filled in the separation grooves 300 are formed by thermal oxidation. Accordingly, groove width W of the side grooves 400 and separation grooves 300 is preferably not less than 1 μm. When the groove width W is 1 μm, the thickness d0 of the upper insulating films 50 formed on the semiconductor substrate 10 by thermal oxidation is set to about 2 μm. When the groove width W is 0.5 μm, the thickness d0 of the upper insulating films 50 is set to about 1.5 μm.

By making the groove width W minute as described above, the side grooves 400 and separation grooves 300 can be filled with the oxidized films by only the step of thermal oxidation. In this case, the surfaces of the upper insulating films 50 formed on the semiconductor substrate are flat, and there is no roughness above the side grooves 400 and separation grooves 300. Accordingly, it is not necessary to perform a flattening step, thus shortening the manufacturing process of the semiconductor device 1.

The side grooves 400 and separation grooves 300 are not necessarily formed simultaneously. However, by simultaneously forming the side grooves 400 and separation grooves 300, the side insulating films 40 and insulating separation regions 30 can be positioned with higher accuracy. Moreover, the manufacturing process can be shortened.

The bottom surface of the vibrators 21 and 22 are not covered with insulating films and can be a little etched when the recess 100 is formed. However, the bottom surfaces of the insulating separation regions 30 and the vibrators and 22 which are exposed in the recess 100 are substantially in a same plane.

Similar to the semiconductor device 1 according to the first embodiment, in the semiconductor device 1 according to the second embodiment, the side surface portions of the vibrators 21 and 22 which are separated from the semiconductor substrate 10 by release etching are covered with the side insulating films 40, and the thicknesses of the vibrators 21 and 22 are determined by the depth t of the side grooves 400. Accordingly, the thicknesses of the vibrators 21 and 22 depend on the performance of the D-RIE apparatus.

The recess 100 is formed by isotropic etching instead of the D-RIE process. This can reduce the manufacturing cost of the semiconductor device 1 and increase the throughput thereof.

As described above, in the method of manufacturing the semiconductor device 1 according to the second embodiment of the present invention, the side insulating films 40 and insulating separation regions 30 are simultaneously formed by performing thermal oxidation to fill the side grooves 400 and separation grooves 300 with the oxidized films. Moreover, the recess 100 is formed by only isotropic etching. It is therefore possible to provide a method of manufacturing a semiconductor device 1 which can form the insulating separation regions 30 while preventing an increase in the manufacturing process. The other effects thereof are substantially the same as those of the first embodiment, and the redundant description thereof is omitted.

### <Modification>

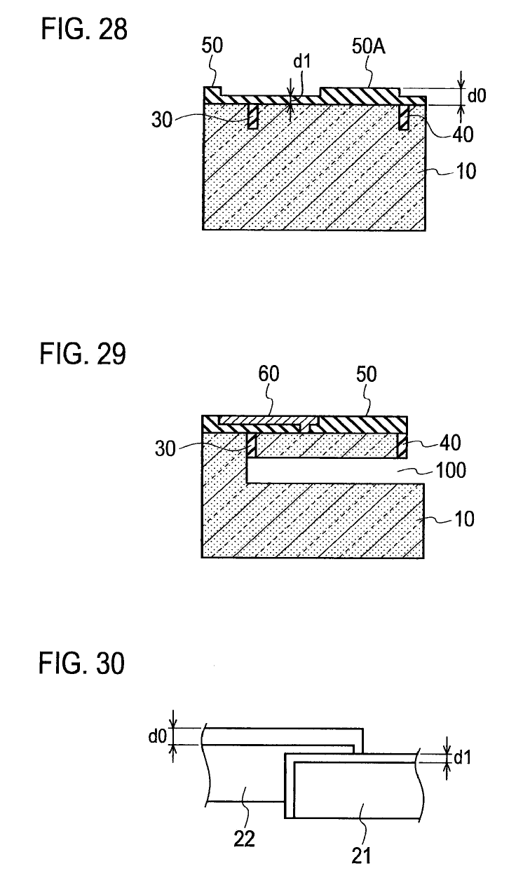

FIGS. 22A and 22B show an example in which the upper insulating films 50 on the vibrators 21 and 22 are etched back to an equal thickness. However, in the case of detecting vertical acceleration, the semiconductor device 1 is manufactured with each of the upper insulating films 50 on the vibrators 21 or 22 partially etched back. Herein the vertical acceleration is acceleration in the thickness direction of the semiconductor substrate 10. FIG. 28 shows an example in which each of the upper insulating films 50(50A) on the vibrators 22 is partially etched back.

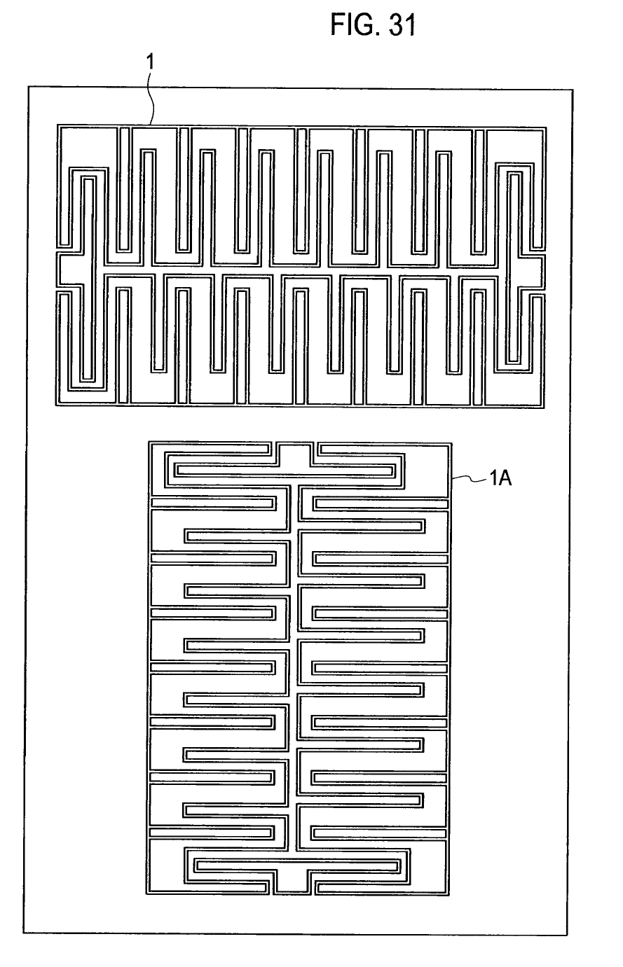

When there is a difference in thickness between the upper insulating films 50 on the vibrator 21 and those on the vibrators 22, because of a difference in stress therebetween, warpage of the beams of the vibrator 21 is different from warpage of the vibrators 22. FIG. 29 shows an example in which the vibrators 22 are formed without etching back the upper insulating films 50. When the upper insulating films 50 on the vibrators 22 are thicker than that on the vibrator 21 like this, as shown in FIG. 30, the upper surfaces of the free ends of the vibrators 22 are higher than the upper surfaces of the free ends of the vibrator 21. The vertical acceleration can be therefore detected.

### Other Embodiments

It should not be understood that the description and the drawings, which form a part of the disclosure of the above-described first and second embodiments, limit this invention. From this disclosure, a variety of alternative embodiments, examples and operation technologies will be obvious for those skilled in the art.

For example, as shown in FIG. 31, two pairs of the vibrators may be used to configure an accelerometer detecting accelerations in the X and Y directions. In the example shown in FIG. 31, the semiconductor device 1 serves as an accelerometer detecting the acceleration in the X direction while a semiconductor device 1A serves as an accelerometer detecting the acceleration in the Y direction. As shown in FIG. 31, the accelerometer detecting acceleration in the X direction has the free ends of the vibrators extending in the direction perpendicular to the direction where the free ends of the vibrators of the accelerometer detecting acceleration in the Y direction extends. Alternatively, a pair of vibrators detecting vertical acceleration (in the Z direction) may be added to the accelerometer in FIG. 31 to configure an accelerometer detecting three dimensional acceleration.

Moreover, although the semiconductor device 1 is an accelerometer in the aforementioned examples, the semiconductor device according to the embodiment of the present invention may be a SAW device or GBAR, for example, other than MEMS devices. The present invention is applicable to method of manufacturing semiconductor devices having vibrators other than the accelerometers, for example, such as gyrosensors.

As described above, it is obvious that the present invention includes various embodiments and the like not described above. Accordingly, the technical scope of the present invention is determined by only the invention elements according to claims appropriate from the viewpoint of the above explanation.

What is claimed is:

1. A method of manufacturing a semiconductor device which includes a plurality of beam-shaped vibrators each having a free end extended in a recess formed in an upper surface of a semiconductor substrate and a fixed end fixed to the semiconductor substrate, the method comprising:
partially etching the upper surface of the semiconductor substrate to form side grooves and expose side surfaces of the vibrators;
partially etching the upper surface of the semiconductor substrate to form separation grooves where insulating separation regions between the vibrators and the semiconductor substrate are to be formed;
thermally oxidizing surfaces of the separation grooves to form the insulating separation region composed of oxidized films filled in the separation grooves;
thermally oxidizing the side surfaces of the vibrators to form side insulating film; and
performing release etching of the semiconductor substrate using the side insulating film as a mask to expose bottom surfaces of the vibrators and form the vibrators arranged in the recess formed in the semiconductor substrate.

2. The method of claim 1, wherein the side grooves and the insulating separation regions are simultaneously formed.

3. The method of claim 2, wherein the thermal oxidation of the surfaces of the separation grooves is performed simultaneously with the thermal oxidation of the side surfaces of the vibrators.

4. The method of claim 2, wherein the vibrators provided with the insulating separation regions between the free ends and the semiconductor substrate and the vibrators having free ends which are electrically connected to the semiconductor substrate are alternately arranged.

5. The method of claim 2, further comprising:
forming an upper insulating film on each of the vibrators;
removing a part of the upper insulating film to form an opening; and
forming a metallic electrode on the upper insulating film, the metallic electrode being electrically connected to each of the vibrators at the opening.

6. The method of claim 5, wherein the upper insulating film includes an oxidized film formed by thermal oxidizing the semiconductor substrate.

7. The method of claim 2, wherein each of the separation grooves has a width of not more than 1 μm.

8. The method of claim 2, the semiconductor substrate is a silicon substrate.

9. The method of claim 1, wherein the side insulating films are formed by thermally oxidizing the surfaces of the side grooves to fill the side grooves with oxidized films.

10. The method of claim 9, wherein the side insulating films and insulating separation regions are simultaneously formed.

11. The method of claim 9, wherein at the step of release etching, a part of the semiconductor substrate in contact with the side surface of the vibrators and a part of the semiconductor substrate in contact with the bottom surface of the vibrators are continuously etched.

12. The method of claim 9, wherein the semiconductor substrate is a silicon substrate.

13. The method of claim 9, wherein an upper insulating film is formed on the vibrators simultaneously with the thermal oxidation of the surfaces of the side grooves and separation grooves.

14. The method of claim 13, further comprising:
removing a part of the upper insulating film on each of the vibrators to form an opening; and
forming a metallic electrode on the upper insulating film, the metallic electrode being electrically connected to each of the vibrators at the opening.

15. The method of claim 9, wherein the side grooves and separation grooves have widths of not more than 1 μm.
